(19) United States
(12) Patent Application Publication
(10) Pub. No.: US 2008/0179043 A1
(43) Pub. Date: Jul. 31, 2008

(54) Heat sink fin with joining structure

(75) Inventor: Han-Chung Ho, Chung-Ho City (TW)

Correspondence Address: RABIN & Berdo, PC, 1101 14TH STREET, NW, SUITE 500, WASHINGTON, DC, 20005, US

(73) Assignee: Cooler Master Co., Ltd., Taipei County (TW)

(21) Appl. No.: 11/698,027

(22) Filed: Jan. 26, 2007

(51) Int. Cl. H05K 7/20

(52) U.S. Cl. 165/78; 165/185; 361/704; 257/722

(57) ABSTRACT

A heat sink fin with joining structure is provided, the heat sink fin is joined with and spaced from other heat sink fins mutually, so as to from a heat sink. The heat sink fin includes a plate and at least one inserting piece. The plate has at least one inserted slot formed in the plate near an edge thereof. The inserting piece extends from the edge of the plate corresponding to the inserted slot and has a buckled hole and a deformable buckling portion. The position of the inserted slot is corresponding to that of the inserting piece of another heat sink fin, and the inserted slot is provided for the inserting piece of the neighboring heat sink fin to be inserted into, and then the buckling portion of the heat sink fin is deformed and buckled into the buckled hole of the neighboring heat sink fin.

### BACKGROUND OF THE INVENTION

1. Field of Invention

The present invention relates to a heat sink fin, and more particularly to a heat sink fin with joining structure, for making the heat sink fin be mutually buckled with other heat sink fins to form a heat sink.

2. Related Art

In order to dissipate heat from the electronic component, such as central processing unit (CPU), that generates heat with high thermal power to maintain operation under a normal temperature, a heat sink is provided to contact with electronic component the for dissipating heat. The commonly used heat sinks include aluminum extrusion and die casting heat sinks, and both the above two kinds of heat sinks are limited by the manufacturing, as a result, the spacing distance between the heat sink fins and the aspect ratio of the heat sink fins have a certain limitation, the number of the heat sink fins of a single heat sink is difficult to be increased, thus, the heat sink area is limited, and the heat sink area is difficult to be increased according to different electronic components of different thermal power.

In view of the above problems, heat sink fins that are capable of mutually joined with each other are provided. This kind of heat sink fin has joining structure, so as to make each heat sink fin be mutually joined with the neighboring heat sink fin, to form a heat sink.

Taiwan Patent Publication No. M294,694 discloses a heat sink fin structure, wherein a stamping operation is directly performed on the heat sink fin, so as to form a inserted slot on the heat sink fin and a inserting piece extending from the heat sink fin. A latched hole is formed in the inserting piece, and a latching piece is formed on an inner peripheral of the inserted slot. The inserting piece of the neighboring heat sink fin is inserted in the inserted slot of this heat sink fin, and the latching piece of the inserted slot is engaged into the latched hole of the inserting piece of the neighboring heat sink fin, so that the heat sink fins are mutually joined with each other to form a heat sink. However, in No. M294,694, the inserting piece formed between the neighboring heat sink fins increases the flow resistance between the heat sink fins, such that the thermal convection is negatively affected.

In U.S. Pat. No. 6,789,609, a latched hole is formed in a flange extending from an edge of the heat sink fin, and a protrusion with V-shaped cross-section is formed on the edge of the flange. The protrusion with V-shaped cross-section of the neighboring heat sink fin is engaged in the latched hole of the heat sink fin, such that the heat sink fins are mutually joined with each other to form a heat sink. The joining structure of U.S. Pat. No. 6,789,609 is located on the edge of the heat sink fin, and the protruding is not formed between the neighboring heat sink fins, which effectively reduces the flow resistance.

However, patents of No. M294,694 and U.S. Pat. No. 6,789,609 still have their problems. Firstly, in the joining structure of the heat sink fins in the above two cases and the currently used heat sink fins, the design of joining structure with the latched hole is adopted, and complex assembling processes are involved, so that the inserting the inserting piece or protrusion cannot be achieved by a machine, but the labor power is required to sequentially join the heat sink fins together. Next, in the joining structure of the heat sink fin in the above two cases and the currently used heat sink fins, the joining structures only generate the fixing effect along the normal direction of the heat sink fins, but lack of the fixing effect along the direction parallel to the heat sink fins, so that a plurality of groups of buckling structures is required to generate a complete fixing effect. Meanwhile, due to lacking of the fixing effect along the direction parallel to the heat sink fin, it is difficult to form a flat contact surface on the flange of the heat sink fins to make the heat sink fins join together. Thus, usually, a welding process is further required to fix the heat sink fins on a heat sink base, which increases the manufacturing steps and the manufacturing cost.

### SUMMARY OF THE INVENTION

In view of the above problems, the object of the present invention is to provide a heat sink fin with joining structure, for effectively joining a plurality of heat sink fins together to reinforce the firmly joining effect between the heat sink fins.

In order to achieve the above objective, a heat sink fin with joining structure of the present invention is provided, wherein the heat sink fin is joined with and spaced from othe heat sink fins so as to form a heat sink. The heat sink fin includes a plate and at least one inserting piece. The heat sink fin has at least one inserted slot formed in the plate near an edge thereof. The inserting piece extends from the edge of the plate corresponding to the inserted slot and has a buckled hole and a deformable buckling portion. The position of the inserted slot is corresponding to the position of the inserting piece of a neighboring heat sink fin, so that the inserted slot is provided for the inserting piece of the neighboring heat sink fin to be inserted into, and the buckling portion of the heat sink fin is deformed and buckled into the buckled hole of the neighboring heat sink fin, and thus, the heat sink fin is buckled with the neighboring heat sink fin.

The advantage of the present invention lies is that, in the provided heat sink fin with joining structure, the buckling portion leans against the inserting piece inserted into the inserted slot, so as to generate the fixing effect along the direction parallel to the plate, and to make the heat sink fins be closely joined with each other and not easily dropped off. In addition, in the design of the inserted slot of the present invention, the effect of joining and fixing is achieved by firstly inserting the inserting piece of the heat sink fin into the inserted slot of the neighboring heat sink fin, and then making the buckling portion be deformed. The above two steps are easily achieved by a machine instead of manual work, and the batch processing is performed to reduce the manufacturing cost and the cost of labor power.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a perspective view of a first embodiment of the present invention;

FIG. 2 is a perspective view of the first embodiment of the present invention from another viewing angle;

FIG. 3 is an exploded view of the first embodiment of the present invention;

FIG. 4A is a perspective view of the first embodiment of the present invention;

FIGS. 4B and 4C are partial enlarged views of the buckling method of the buckling portion in different configurations according to the first embodiment of the present invention;

FIG. 5 is a cross-sectional view of the first embodiment of the present invention;

FIG. 6 is a perspective view of the first embodiment of the present invention;

FIGS. 7A and 7B are partial enlarged views of a second embodiment of the present invention;

FIGS. 7C and 7D are partial enlarged views of the buckling method of the buckling portion in different configurations according to the second embodiment of the present invention;

FIG. 8 is a partial enlarged view of a third embodiment of the present invention; and

FIG. 9 is a perspective view of the fourth embodiment of the present invention.

### DETAILED DESCRIPTION OF THE INVENTION

In order to make the objectives, constructions, features, and functions of the present invention be more comprehensible, the detailed description is given below through the embodiments.

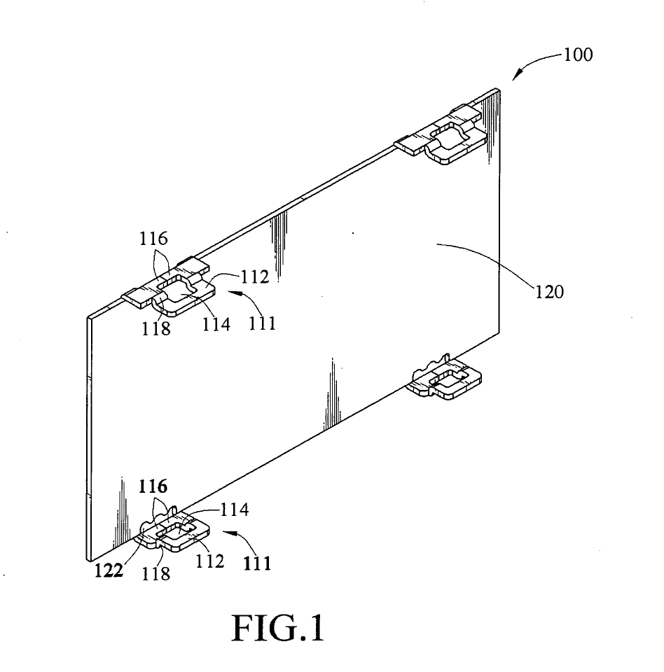

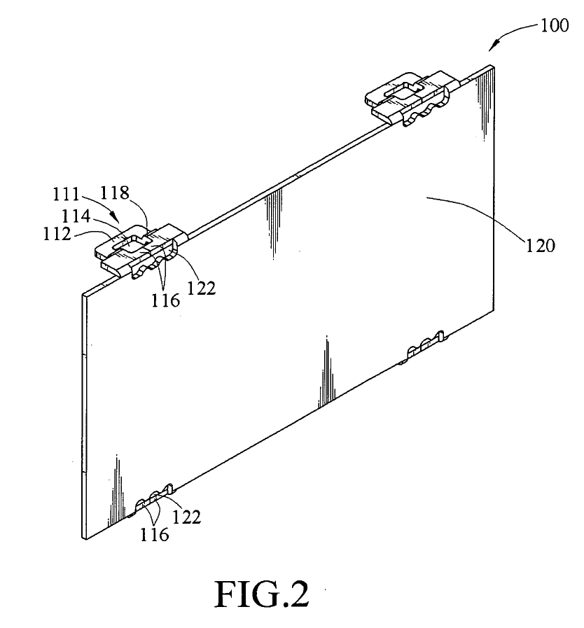

Referring to FIGS. 1 and 2, a heat sink fin with joining structure 100 of a first embodiment of the present invention is shown. The heat sink fin 100 is provided to be joined with and spaced from other heat sink fins 100 mutually, so as to from a heat sink.

Referring to FIGS. 1 and 2, the heat sink fin 100 includes a plate 120 and a plurality of inserting pieces 111. The plate 120 has a plurality of inserted slots 122, with the number corresponding to that of the inserting pieces 111, formed in the plate 120 near an edge of the plate 120, and each inserting piece 111 perpendicularly extends at the side edge of the plate 120 respectively, corresponding to each inserted slot 122. Each inserting piece 111 has a overlapping portion 112, a buckled hole 114, and a deformable buckling portion 116, wherein the buckling portion 116 is formed on the edge of the plate 120 and adjacent to the corresponding inserted slot 122. The overlapping portion 112 is connected to the buckling portion 116, and is formed on an end of the inserting piece 111 away from the plate 120. A level structure 118 is formed at the connecting part of the buckling portion 116 and the overlapping portion 112, such that a height difference exists between the overlapping portion 112 and the buckling portion 116, and the overlapping portion 112 corresponds to the inserted slot 122 of another neighboring heat sink fin 100. The buckled hole 114 is formed in the overlapping portion 112, corresponding to the buckling portion 116 of the neighboring heat sink fin 100. The inserted slot 122 is used to make the overlapping portion 112 of the inserting piece 111 of the back neighboring heat sink fin 100 be inserted into the inserted slot 122, such that the overlapping portion 112 leans against and overlap the buckling portion 116 of the neighboring heat sink fin 100 from the outer side, and it is located above the corresponding buckled hole 114. In this embodiment, the buckling portion 116 is cut in the middle thereof to form two buckling pieces to be pressed and deformed from outer side to inner side, so as to be embedded into the corresponding buckled hole 114.

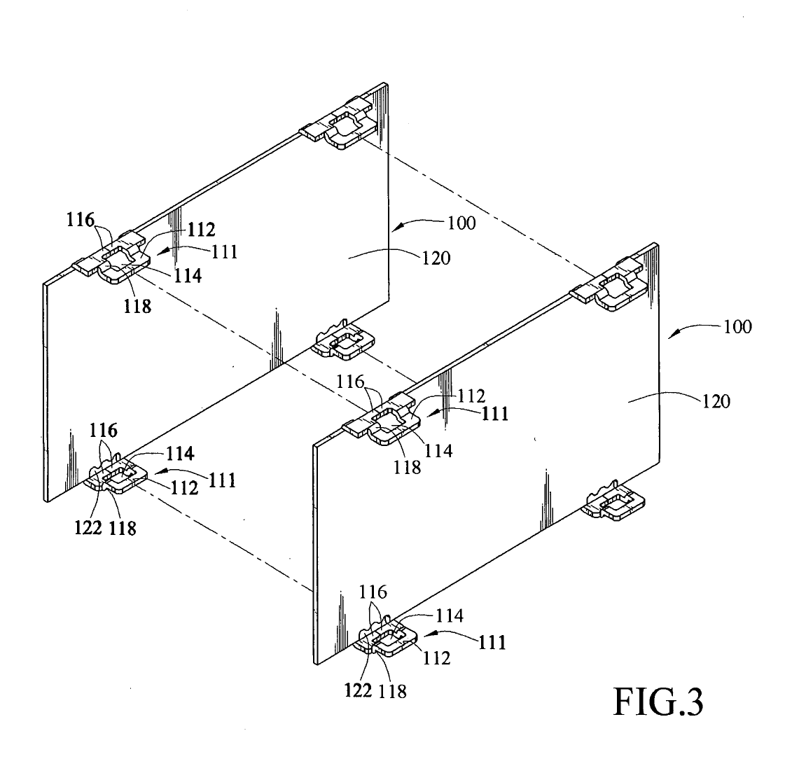

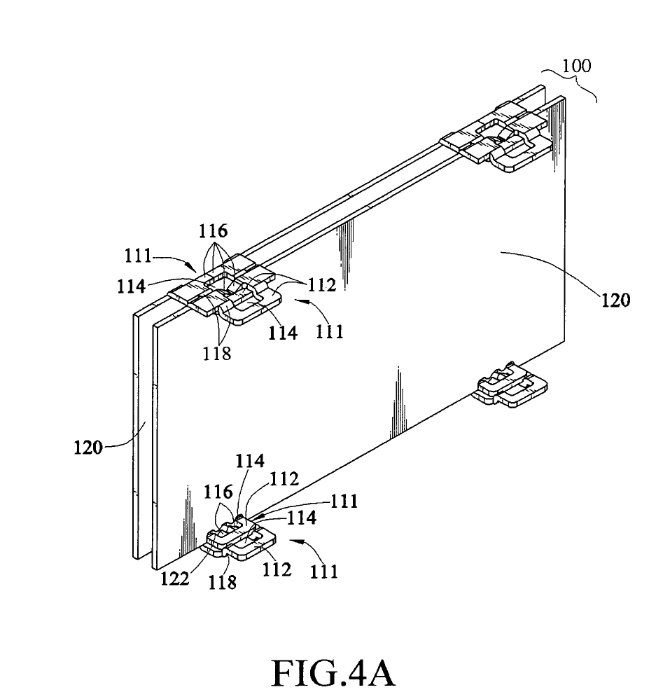

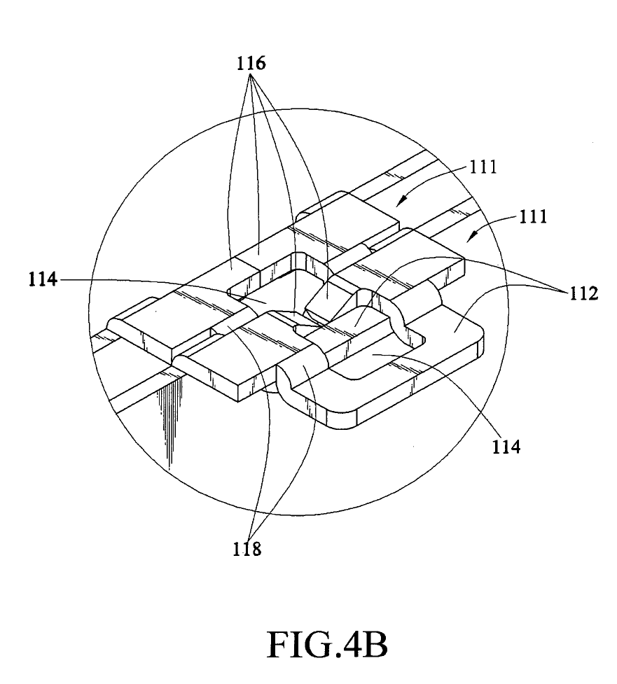

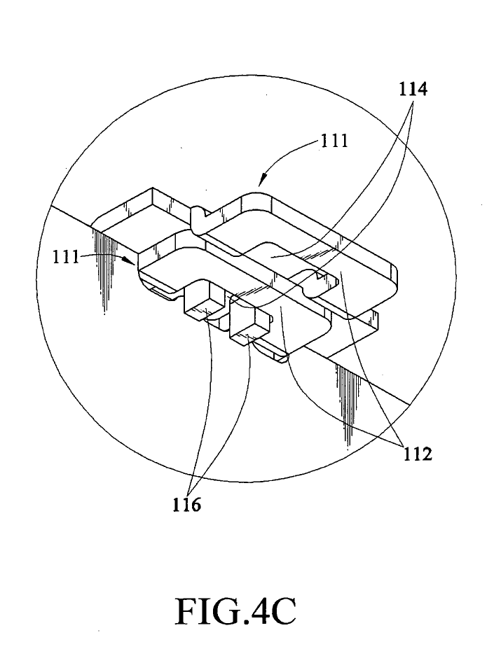

Referring to FIGS. 3, 4A, and 4B, when the heat sink fin 100 is assembled, the inserting piece 111 of the neighboring heat sink fin 100 passes through the inserted slot 122 of the front heat sink fin 100 (the extending direction of the inserting piece 111 is defined as the front direction), until the overlapping portion 112 of the inserting piece 111 of the back neighboring heat sink fin 100 leans against and overlap the buckling portion 116 of the inserting piece 111 of the front heat sink fin 100. At this time, the buckling portion 116 on the front heat sink fin 100 leans against the inserting piece 111 of the back heat sink fin 100 from the outer side, and it is located above the buckled hole 114. Next, the buckling portion 116 is pressed and deformed outer side to inner side, and the buckling portion is depressed inwards, and embedded in the buckled hole 114 of the back heat sink fin 100, thus the two heat sink fins 100 are joined with each other. However, another configuration of the buckling portion 116 being deformed and depressed inwards upon being pressed is shown in FIG. 4C, and the pressing piece 116 is pressed into the buckled hole 114 with a rectangular bending angle to be closely buckled with the buckled hole 114.

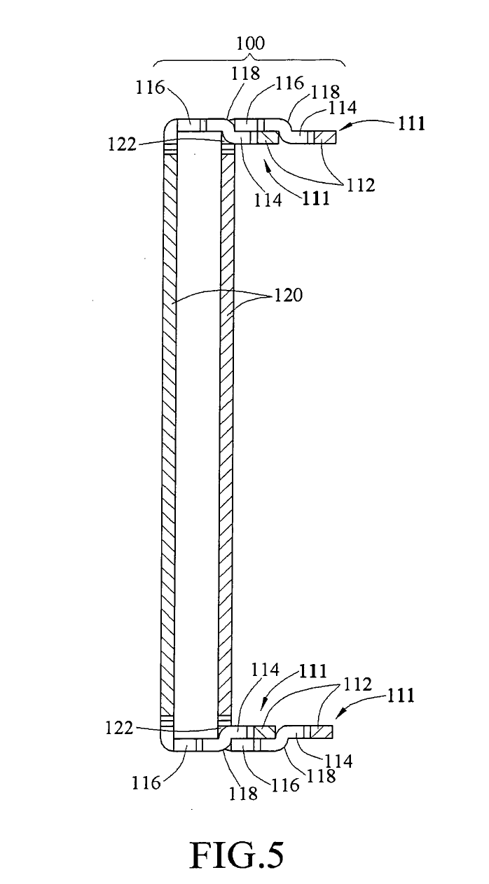

Referring to FIGS. 4A, 4B, and 5, the buckling portion 116 leans against the overlapping portion 112 from the outer side and it is buckled in the buckled hole 114, so that a couple of inserting pieces 111 and inserted slots 122 is respectively disposed on both opposite side edges of the heat sink fin 100, and meanwhile, the fixing effects along the normal direction of the plate 110 and the direction parallel to the plate 110 are achieved, so as to make the two neighboring heat sink fins 100 be closely joined together. Meanwhile, the buckling portion 116 of the present invention is pressed to be deformed after the inserting piece 111 is inserted in the inserted slot 122, and the buckling portion 116 is located on the outer side, which is directly stamped by the machine to be deformed. Therefore, the assembly process of the present invention may be divided into two steps: firstly the inserting piece 111 is inserted in the inserted slot 122, and then, the buckling portion 116 is made to be deformed from the outer side. The two steps are easily achieved by the mechanical process, and the batch process is performed, so as to reduce the manufacturing cost and the cost of labor power.

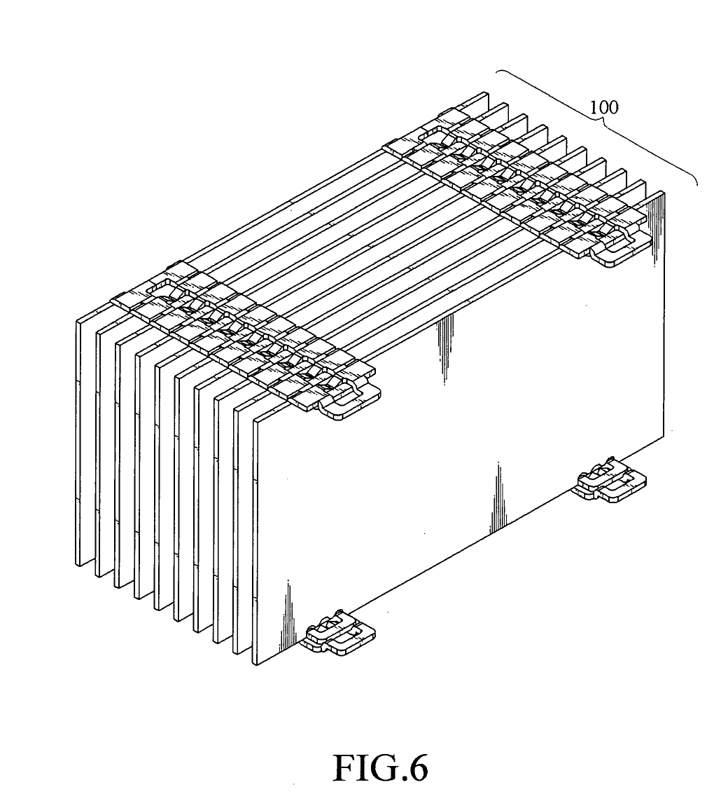

Referring to FIG. 6, a plurality of heat sink fins 100 is arranged in parallel and is joined together to form a heat sink.

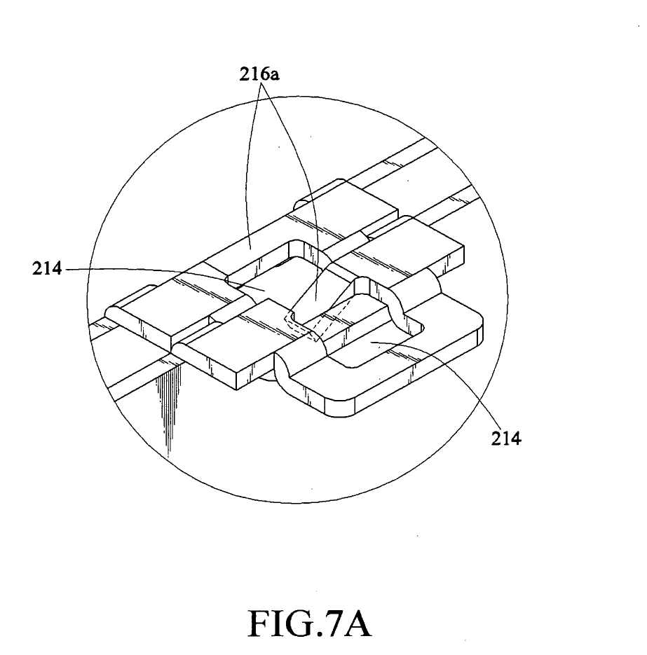

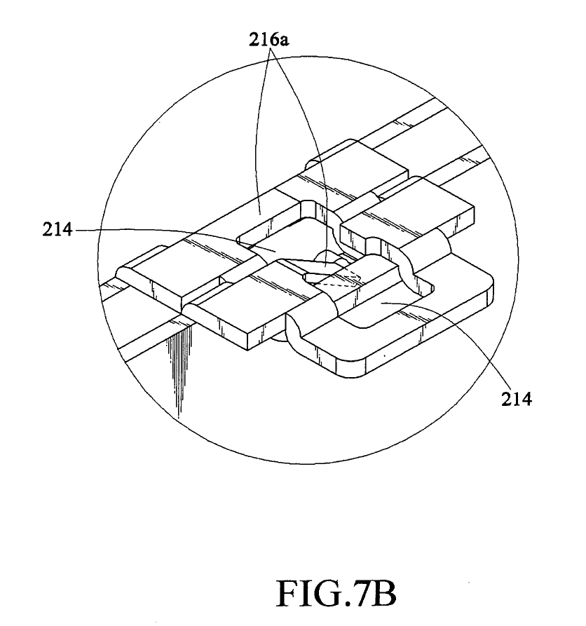

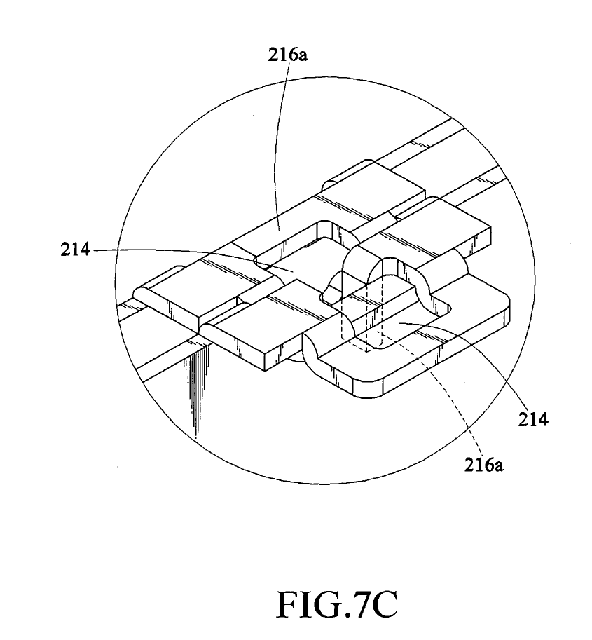

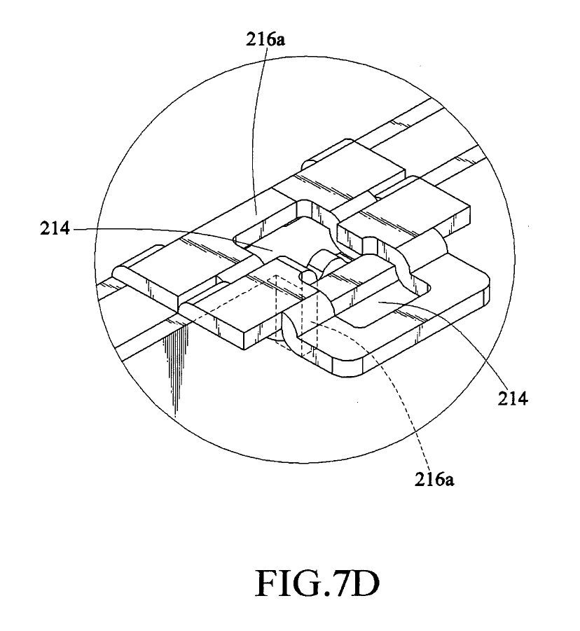

Referring to FIGS. 7A to 7D, a heat sink fin with a jointing and fixing structure of a second embodiment of the present invention is shown. Most of the structures, joining relations, and operating principles are the same as that of the first embodiment, with the difference lies in that, in the second embodiment of the present invention, the buckling portion 216a is cut on the left end or the right end of the buckling portion 216a, so as to form a single strip-shaped buckling piece. The single strip-shaped buckling piece is pressed and deformed to be embedded in the buckled hole 214 of another neighboring heat sink fin, so as to achieve the effect of fixing the heat sink fins. However, another configuration of the buckling portion 216a being pressed to be deformed and depressed inwards is shown in FIGS. 7C and 7D, and the buckling piece 216a is pressed into the buckled hole 114 with a rectangular bending angle to be closely buckled with the buckled hole 114.

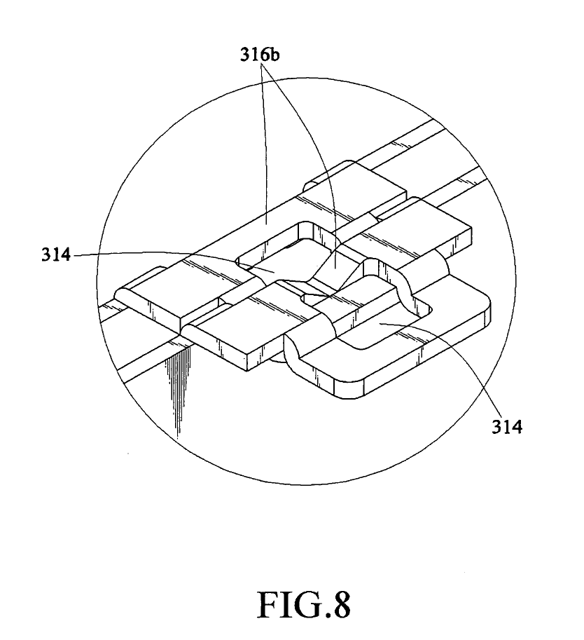

Referring to FIG. 8, it shows a heat sink fin with joining structure according to a third embodiment of the present invention. Most of the structures, joining relations, and operating principles are the same as that of the first and second embodiments, with the difference lying in that, in the third embodiment of the present invention, the buckling portion 316b is a continuous piece with excellent metal ductility, which is depressed to be deformed into a V shape and embedded in the buckled hole 314, so as to achieve the effect of fixing the heat sink fins.

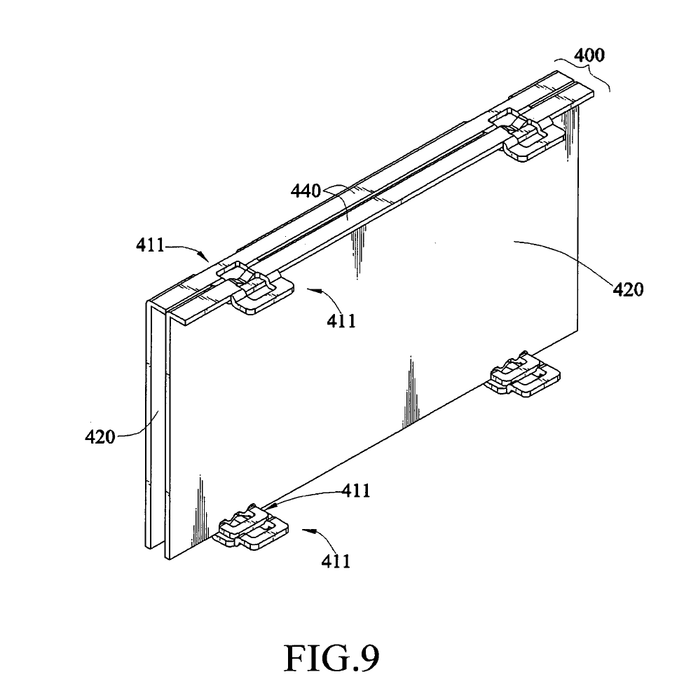

Moreover, referring to FIG. 9, it shows a heat sink fin with joining structure 400 according to a fourth embodiment of the present invention. The joining relations and the operating principles of the fourth embodiment are substantially the same as that of the third embodiment, with the difference lying in that, in the fourth embodiment, the plate 420 has a flange 440 formed on the edge of the plate 420, and extends along both side edges of the inserting piece 411, and perpendicular to the plate 420. The present invention achieves an excellent fixing effect, so that the horizontal flanged edge 440 of the heat sink fin 400 may form a stable and flat contact surface for directly contacting with the heat source or adhering on a heat sink base.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat sink fin with joining structure, comprising:
a plate having at least one inserted slot formed in the plate near an edge of the plate; and
at least one inserting piece, extending from the edge of the plate corresponding to the inserted slot, and having a buckled hole and a buckling portion, wherein the inserted slot is provided for the inserting piece of another neighboring heat sink fin to be inserted into, and the buckling portion of the inserting piece of the heat sink fin is deformed and buckled into the buckled hole of the inserting piece of the neighboring heat sink fin.

2. The heat sink fin with joining structure according to claim 1, wherein the inserting piece perpendicularly extends from the edge of the plate.

3. The heat sink fin with joining structure according to claim 1, wherein the inserting piece comprises an overlapping portion on an end of the inserting piece away from the plate.

4. The heat sink fin with joining structure according to claim 3, wherein a height difference exists between the overlapping portion and the buckling portion.

5. The heat sink fin with joining structure according to claim 4, wherein the buckled hole is formed in the overlapping portion, and the overlapping portion is provided to lean against and overlap the buckling portion of the neighboring heat sink fin.

6. The heat sink fin with joining structure according to claim 1, wherein the buckling portion is cut in the middle thereof to form two buckling pieces to be deformed and embedded in the buckled hole.

7. The heat sink fin with joining structure according to claim 6, wherein the pressing piece is deformed into a rectangular bending angle to be embedded in the buckled hole.

8. The heat sink fin with joining structure according to claim 1, wherein the buckling portion is cut on an end thereof to form a buckling piece to be deformed and embedded in the buckled hole.

9. The heat sink fin with joining structure according to claim 8, wherein the pressing piece is deformed into a rectangular bending angle to be embedded in the buckled hole.

10. The heat sink fin with joining structure according to claim 1, wherein the buckling portion is a continuous piece, for being depressed and embedded in the buckled hole.

11. The heat sink fin with joining structure according to claim 1, wherein the plate has a flange formed on the edge of the plate that the inserting piece extends, and the flange extends on both side edges of the inserting piece.

12. The heat sink fin with joining structure according to claim 11, wherein the flange is perpendicular to the plate.
